(19) United States
(12) Patent Application Publication
(10) Pub. No.: US 2014/0035684 A1
(43) Pub. Date: Feb. 6, 2014

(54) CONTROL CIRCUIT AND APPARATUS FOR DIGITALLY CONTROLLED OSCILLATOR

(71) Applicants: SAMSUNG ELECTRO-MECHANICS CO., LTD., Gyunggi-do (KR); RESEARCH & BUSINESS FOUNDATION SUNGK, Gyunggi-do (KR)

(72) Inventors: Yoo Sam NA, Gyunggi-do (KR); Kang Yoon LEE, Seoul (KR); Dong Su LEE, Gyunggi-do (KR); Hyung Gu PARK, Seoul (KR); Hong Jin KIM, Seoul (KR); Gyu Suck KIM, Gyunggi-so (KR); Young Gun PU, Jeju-do (KR)

(73) Assignees: RESEARCH & BUSINESS FOUNDATION SUNGKYUNKWAN UNIVERSITY, Gyunggi-do (KR); SAMSUNG ELECTRO-MECHANICS CO., LTD., Gyunggi-do (KR)

(21) Appl. No.: 13/675,630

(22) Filed: Nov. 13, 2012

(30) Foreign Application Priority Data
Jul. 31, 2012 (KR) 10-2012-0084099

(51) Int. Cl. H03L 5/00; H03L 7/06

(52) U.S. Cl. CPC H03L 5/00; H03L 7/06
USPC 331/15; 331/18

(57) ABSTRACT

There are provided a control circuit for a digitally controlled oscillator and a control apparatus for a digitally controlled oscillator using the same. The control circuit for a digitally controlled oscillator includes: a peak detection circuit detecting amplitude of a signal output from the digitally controlled oscillator; and a transconductance control circuit comparing an output of the peak detection circuit with a predetermined reference signal to control a transconductance value of a negative transconductance circuit included in the digitally controlled oscillator.

### CROSS-REFERENCE TO RELATED APPLICATIONS

This application claims the priority of Korean Patent Application No. 10-2012-0084099 filed on Jul. 31, 2012, in the Korean Intellectual Property Office, the disclosure of which is incorporated herein by reference.

### BACKGROUND OF THE INVENTION

1. Field of the Invention

The present invention relates to a control circuit for a digitally controlled oscillator and a control apparatus for a digitally controlled oscillator using the same.

2. Description of the Related Art

A phase locked loop (PLL) circuit for generating a carrier frequency having applications in a 4th generation (4G) system such as the long term evolution (LTE) system, and the like, wireless connection in a cellular phone such as Bluetooth, a global positioning system (GPS) system, wideband code division multiple access (WCDMA), and the like, a wireless local area network (LAN) such as an 802.11a/b/g LAN, or the like, has been widely used. An analog type PLL circuit according to the related art requires a high-speed operable divider and an area thereof cannot be reduced due to a width-length ratio of a metal-oxide semiconductor (MOS), limited according to current source noise or accuracy.

In addition, an analog type PLL circuit occupies a relatively large area due to a loop filter configured of a passive resistor and a capacitor and may have increased current consumption due to including a voltage-controlled oscillator (VCO) buffer, a local oscillator (LO) buffer, an output buffer, and the like, so as to secure a desired analog signal level. In addition, due to features of the analog type PLL circuit sensitive to process characteristics, almost all blocks need to be redesigned whenever a process is changed, which leads to an increase in manufacturing time and costs. Therefore, demand for a digital phase locked loop circuit capable of solving the above problems has been continuously increasing.

In the case of a digital phase locked loop, a wideband frequency and a multiband frequency are required and an LC resonance tank of an oscillator requires a large number of capacitors so as to obtain a wide band in a tuning region, such that the digital phase locked loop occupies a large area. Further, when frequency tuning is performed with a simple passive capacitance value, frequency tuning variations are increased according to a capacitance value, and a gain of the oscillator varies according to the capacitance value, which affects phase noise. In addition, a large amount of current corresponding to the number of capacitors may be consumed, and thus, output amplitude of the digitally controlled oscillator is reduced, such that amplitude required to operate the phase locked loop may not be obtained.

Patent Document 1 relating to a digitally controlled oscillator, discloses a digitally controlled oscillator capable of tuning in a frequency in a broad sense, but does not disclose a gain control or an amplitude control of the digitally controlled oscillator. Moreover, Patent Document 2 relating to a digitally controlled oscillator discloses contents regarding a gain control of a digitally controlled oscillator using a programmable varactor while not disclosing an amplitude control of the digitally controlled oscillator using a negative transconductance circuit.

### RELATED ART DOCUMENT

(Patent Document 1) Korean Patent Laid-Open Publication No. 2012-0023997
(Patent Document 2) US Patent Laid-Open Publication No. 2008/0136544

### SUMMARY OF THE INVENTION

An aspect the present invention provides a control circuit and apparatus for a digitally controlled oscillator, capable of controlling amplitude of a digitally controlled oscillator using a digital signal generated by an amplitude control unit and compensating for a frequency change generated by a PVT condition using a digital signal generated by a frequency control unit.

According to an aspect of the present invention, there is provided a control circuit for a digitally controlled oscillator, including: a peak detection circuit detecting amplitude of a signal output from the digitally controlled oscillator; and a transconductance control circuit comparing an output of the peak detection circuit with a predetermined reference signal to control a transconductance value of a negative transconductance circuit included in the digitally controlled oscillator.

The transconductance control circuit includes: a first comparator comparing a magnitude of the amplitude of the signal output from the digitally controlled oscillator with a magnitude of amplitude of a predetermined first reference signal to generate a digital output signal according to comparison results.

The first comparator may generate a logic high signal as the digital output signal when the magnitude of the amplitude of the signal output from the digitally controlled oscillator is lower than that of the first reference signal and may generate a logic low signal as the digital output signal when the magnitude of the amplitude of the signal output from the digitally controlled oscillator is higher than that of the first reference signal.

The transconductance control circuit may include: a transconductance bank including a plurality of transconductance unit cells operated according to the digital output signal generated by the first comparator.

The transconductance unit cells each may be sequentially operated when the digital output signal is a logic high signal.

The transconductance control circuit may include: a second comparator comparing the signal output from the digitally controlled oscillator with a predetermined second reference signal to generate an analog control signal according to comparison results.

According to another aspect of the present invention, there is provided a control circuit for a digitally controlled oscillator, including: a counter circuit detecting a frequency of a signal output from the digitally controlled oscillator; a first frequency controller comparing an output of the counter circuit with a predetermined reference frequency to control capacitance of a capacitor bank included in the digitally controlled oscillator; and a second frequency controller detecting the output of the counter circuit to control capacitance of a varactor included in the digitally controlled oscillator.

The first frequency controller may generate a logic high signal as a digital signal when it is determined that the frequency of the signal output from the digitally controlled oscillator is higher than the predetermined reference frequency and may generate a logic low signal as a digital signal when it is determined that the frequency of the signal output from the digitally controlled oscillator is lower than the predetermined reference frequency.

The capacitor bank may include a plurality of cells in which resistors and capacitor units are connected in parallel, the capacitor units being selectively controlled by a plurality of bits output from the first frequency controller.

The varactor may be controlled according a magnitude of a voltage applied thereto, the magnitude of the voltage being controlled by a plurality of bits output from the second frequency controller.

A gain of the digitally controlled oscillator may be constantly maintained by the plurality of bits output from the second frequency controller.

According to another aspect of the present invention, there is provided a control apparatus for a digitally controlled oscillator, including: a digitally controlled oscillator core unit including a negative transconductance circuit, a capacitor bank, and a varactor; an amplitude control unit including a peak detection circuit detecting amplitude of a signal output from the digitally controlled oscillator core unit and a transconductance control circuit comparing an output of the peak detection circuit with a predetermined reference signal to control a transconductance value of the negative transconductance circuit; and a frequency control unit controlling capacitance of the capacitor bank and the varactor to control a frequency of the signal output from the digitally controlled oscillator core unit.

The transconductance control circuit may include a first comparator comparing a magnitude of the amplitude of the signal output from the digitally controlled oscillator core unit with a magnitude of amplitude of a predetermined first reference signal to generate a digital output signal according to comparison results.

The first comparator may generate a logic high signal as the digital output signal when the magnitude of the amplitude of the signal output from the digitally controlled oscillator is lower than that of the first reference signal and may generate a logic low signal as the digital output signal when the magnitude of the amplitude of the signal output from the digitally controlled oscillator is higher than that of the first reference signal.

The frequency circuit unit may include: a counter circuit detecting the frequency of the signal output from the digitally controlled oscillator core unit; a first frequency controller comparing an output of the counter circuit with a predetermined reference frequency to control the capacitance of the capacitor bank; and a second frequency controller detecting the output of the counter circuit to control the capacitance of the varactor.

The first frequency controller may generate a logic high signal as a digital signal when it is determined that the frequency of the signal output from the digitally controlled oscillator core unit is higher than the predetermined reference frequency and may generate a logic low signal as a digital signal when it is determined that the frequency of the signal output from the digitally controlled oscillator is lower than the predetermined reference frequency.

The capacitor bank may include a plurality of cells in which resistors and capacitor units are connected in parallel, the capacitor units being selectively controlled by a plurality of bits output from the first frequency controller.

The varactor may be controlled according to a magnitude of a voltage applied thereto, the magnitude of the voltage being controlled by a plurality of bits output from the second frequency controller.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a block diagram schematically illustrating a control apparatus for a digitally controlled oscillator according to an embodiment of the present invention;

FIG. 2 is a circuit diagram schematically illustrating the control apparatus for a digitally controlled oscillator of FIG. 1;

FIG. 3 is a block diagram illustrating an amplitude control unit in the control apparatus for a digitally controlled oscillator of FIG. 1 in detail;

FIG. 4 is a circuit diagram illustrating a unit transconductance cell in the control apparatus for a digitally controlled oscillator of FIG. 2 in detail;

FIG. 5 is a block diagram illustrating a frequency control unit in the control apparatus for a digitally controlled oscillator of FIG. 1 in detail;

FIG. 6 is a circuit diagram illustrating a capacitor bank controlled according to the frequency control unit of FIG. 5;

FIG. 7 is a circuit diagram depicting a varactor controlled according to the frequency control unit of FIG. 5; and

FIG. 8 is a block diagram depicting the control apparatus for a digitally controlled oscillator according to the embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

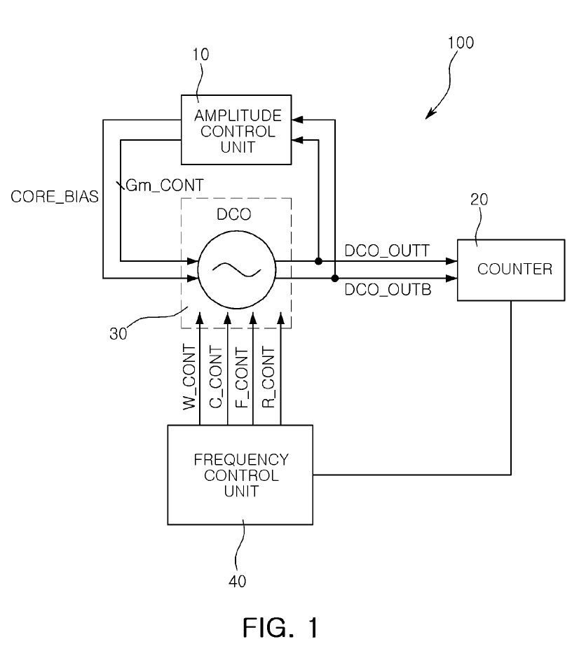

FIG. 1 is a block diagram schematically illustrating a control apparatus for a digitally controlled oscillator according to an embodiment of the present invention.

Referring to FIG. 1, a control apparatus 100 for a digitally controlled oscillator according to an embodiment of the present invention may include a digitally controlled oscillator core unit 30, an amplitude control unit 10, a counter 20, and a frequency control unit 40.

The amplitude control unit 10 receives output signals DCO_OUTT and DCO_OUTB of a digitally controlled oscillator, output from the digitally controlled oscillator core unit 30 to generate feedback signals Gm_CONT and CORE_BIAS. The feedback signals Gm_CONT and CORE_BIAS may respectively be used to control current in a negative transconductance control circuit and the digitally controlled oscillator.

The counter 20 may receive the output signals DCO_OUTT and DCO_OUTB of the digitally controlled oscillator, output from the digitally controlled oscillator core unit 30 to determine a frequency of the output signals DCO_OUTT and DCO_OUTB. The frequency may be determined by counting the number of signals for a predetermined reference time. For example, when the number of signals counted for 1 μs is 2000, the frequency of the signals output from the digitally controlled oscillator is 2 GHz.

The frequency control unit 40 generates output signals W_CONT, C_CONT, F_CONT, and R_CONT based on the frequency of the output signals DCO_OUTT and DCO_OUTB of the digitally controlled oscillator determined by the counter 20. The output signals W_CONT, C_CONT, F_CONT, and R_CONT are digital signals having a plurality of bits and each may have the number of different bits and may be used to control the frequency of the output signals DCO_OUTT and DCO_OUTB of the digitally controlled oscillator. The output signal C_CONT may control the frequency of the output signals of the digitally controlled oscillator to be in a desired frequency band and the output signals F_CONT and R_CONT may control a gain of the output signals of the digitally controlled oscillator to be constant.

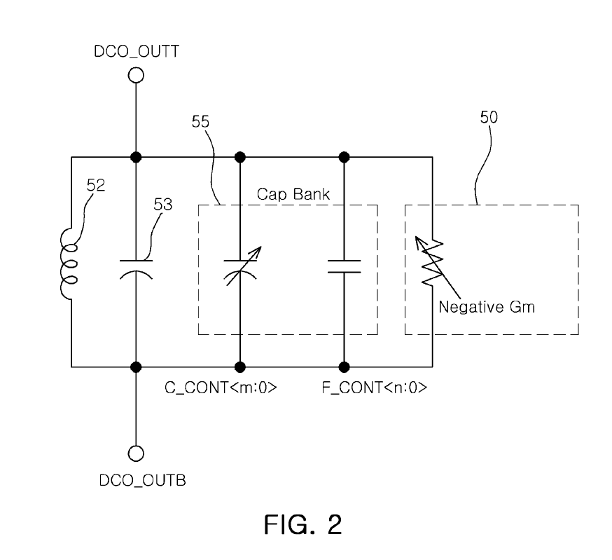

FIG. 2 is a circuit diagram schematically illustrating the control apparatus for a digitally controlled oscillator of FIG. 1.

Referring to FIG. 2, the digitally controlled oscillator according to the embodiment of the present invention may include a passive inductor element 52, a fixed capacitor 53, a capacitor bank 55, and a negative transconductance circuit 50.

The passive inductor element 52 has a fixed value and may have parasitic resistance according to a coil, in addition to inductance. The output signal of the digitally controlled oscillator may be a vibration wave vibrating according to an LC resonance circuit (here, L represents inductance of the passive inductor element and C represents capacitance according to the fixed capacitor and the capacitor bank). The vibration wave may be vibrated while maintaining constant amplitude, but a magnitude of amplitude thereof may be increased or decreased by the parasitic resistance included in the passive inductor element 52.

The negative transconductance circuit 50 may be used to control oscillation of the output signal of the digitally controlled oscillator. When the oscillation of the output signal of the digitally controlled oscillator is increased or decreased according to the parasitic resistance included in the passive inductor element 52, the amplitude of the output signal may be oscillated while being constantly maintained, by controlling the negative transconductance circuit 50.

The capacitor bank 55, a circuit for controlling a capacitance value, may control a frequency by controlling the capacitance value. The frequency of the output signal of the digitally controlled oscillator is represented by the following Equation 1.

$$f = \frac{1}{2 π \sqrt{LC}} \qquad [ Equation 1 ]$$

In Equation 1, L represents an inductance value of the passive inductor element 52 and C represents a capacitance value according to the fixed capacitor 52 and the capacitor bank circuit 55. The frequency of the output signal of the digitally controlled oscillator may increase or decrease according to a process, supply voltage, temperature, and the like, such as PVT (process, voltage, temperature) conditions. Therefore, changes in frequency according to the PVT conditions, and the like, may be compensated for by controlling values of L and C. However, L, an inductance value of the passive inductor element, is fixed and therefore, C, a capacitance value needs to be controlled. The capacitor bank 55 may receive the output signals C_CONT and F_CONT to control the capacitance value. The output signal C_CONT turns a switch connected to the capacitor on or off for frequency coarse tuning to control capacitance and the output signal F_CONT controls a varactor having a small capacitance to finely control the frequency.

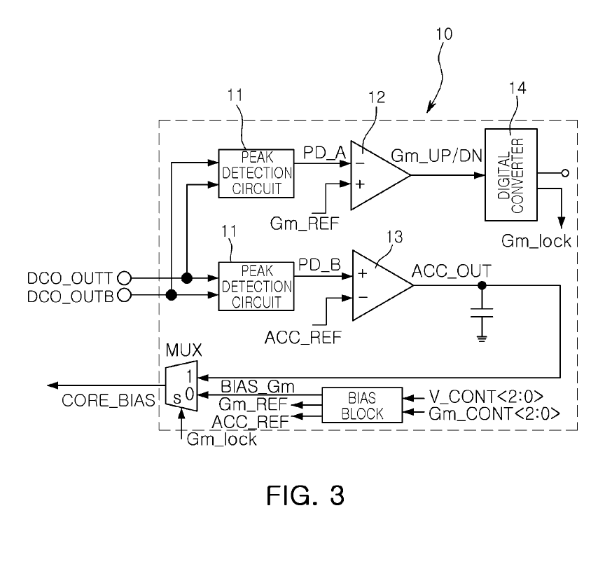

FIG. 3 is a block diagram illustrating an amplitude control unit in the control apparatus for a digitally controlled oscillator of FIG. 1 in detail.

Referring to FIG. 3, the amplitude control unit 10 according to the embodiment of the present invention may include a peak detection circuit 11, a first comparator 12, a second comparator 13, and a digital converter 14.

The peak detection circuit 11 receives the output signals DCO_OUTT and DCO_OUTB of the digitally controlled oscillator to detect a peak amplitude value of the output signals DCO_OUT and DCO_OUTB, thereby generating output signals PD_A and PD_B.

The output signal PD_A generated by the peak detection circuit 11 is transferred to the first comparator 12. The first comparator 12 may be a latch type comparator and may receive the output signal PD_A and a predetermined first reference signal Gm_REF to compare the signals with each other. A signal Gm_UP/DN output from the first comparator 12 may be transferred to the digital converter 14 to generate a digital signal.

As described above, the oscillation of the output signal of the digitally controlled oscillator may be increased or decreased by the parasitic resistance of the inductor element included in the digitally controlled oscillator. The first comparator 12 may compare amplitude of the first reference signal Gm_REF with amplitude of the signal PD_A currently output from the digitally controlled oscillator and accordingly, the output signal of the digitally controlled oscillator may be controlled such that a magnitude of amplitude thereof is not increased or decreased to maintain constant amplitude.

That is, the first comparator 12 generates an output signal Gm_UP when a magnitude of a peak amplitude of the signal PD_A is lower than that of the first reference signal Gm_REF and generates an output signal Gm_DN when the magnitude of the peak amplitude of the signal PD_A is higher than that of the first reference signal Gm_REF, thereby controlling the amplitude of the signal PD_A. An amplitude control method according to the output signal of the first comparator 12 will be described below.

The second comparator 13 may receive the output signal PD_B generated by the peak detection circuit 11 and a predetermined second reference signal ACC_REF to compare the magnitudes of amplitude of the two signals. The second comparator 13 may be an OP-amp type comparator, and a signal output from the second comparator 13 may control amplitude of the output signal of the digitally controlled oscillator and current of the digitally controlled oscillator core unit according to an analog method. The signal output from the second comparator 13 may be transferred to a multiplexer (MUX), and the multiplexer (MUX) may select one of a signal ACC_OUT and a signal BIAS_Gm. A signal Gm_lock applied to the multiplexer (MUX) is a signal output from the digital converter 14. In this case, when the signal Gm_lock is applied to the multiplexer (MUX), the multiplexer (MUX) is operated.

The first comparator 12 and the digital converter 14 connected to the first comparator 12 form a feedback circuit controlling the amplitude of the output signal of the digitally controlled oscillator. A predetermined amount of feedback may be set to control the amplitude of the output signal and when the set amount of feedback is performed, the signal Gm_lock may be generated and output.

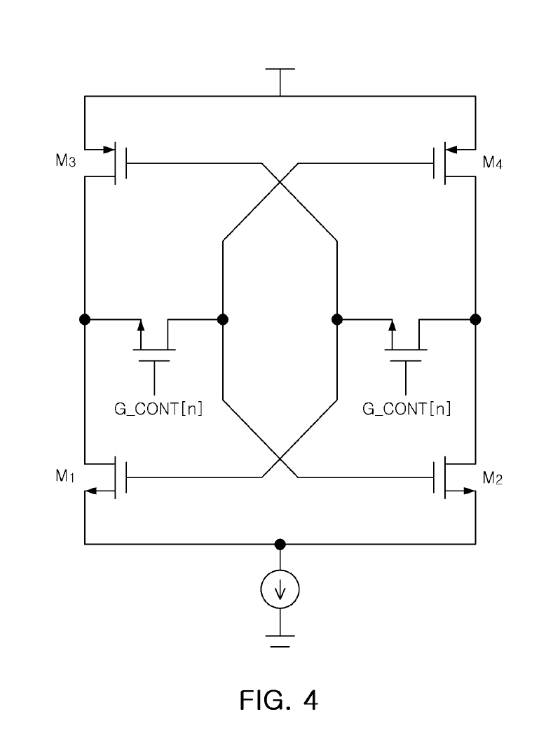

FIG. 4 is a circuit diagram illustrating a unit transconductance cell in the control apparatus for a digitally controlled oscillator of FIG. 2 in detail.

The negative transconductance circuit of the digitally controlled oscillator may include a plurality of unit transconductance cells. The unit transconductance cell included in the digitally controlled oscillator may be controlled according to the output signal generated by the first comparator 12 to control the amplitude of the output signal of the digitally controlled oscillator.

The unit transconductance cell has a cross coupled structure, in which an N-type metal oxide silicon field effect transistor (MOSFET) may serve as a switch. The switch connected to the N-type MOSFET may be operated according to a signal G_CONT [n:0]. The signal G_CONT [n:0] may be a digital signal having n+1 bits. When the signal G_CONT [n:0] has a value of “1”, the unit transconductance cell is turned-on. The signal G_CONT [n:0] of FIG. 4, a signal output from the digital convert unit 14 of FIG. 3, may be controlled by the output signal Gm_UP/DN generated by the first comparator 12.

That is, when the amplitude of the output signal of the digitally controlled oscillator is higher than that of the first reference signal, the signal Gm_UP/DN generates a bit having a value of “0” through the digital convert unit 14 and the unit transconductance cell is not turned-on. On the contrary, when the amplitude of the output signal of the digitally controlled oscillator is lower than that of the first reference signal, the signal Gm_UP/DN generates a bit having a value of “1” through the digital convert unit 14 and the unit transconductance cell is turned-on to increase the amplitude of the output signal of the digitally controlled oscillator.

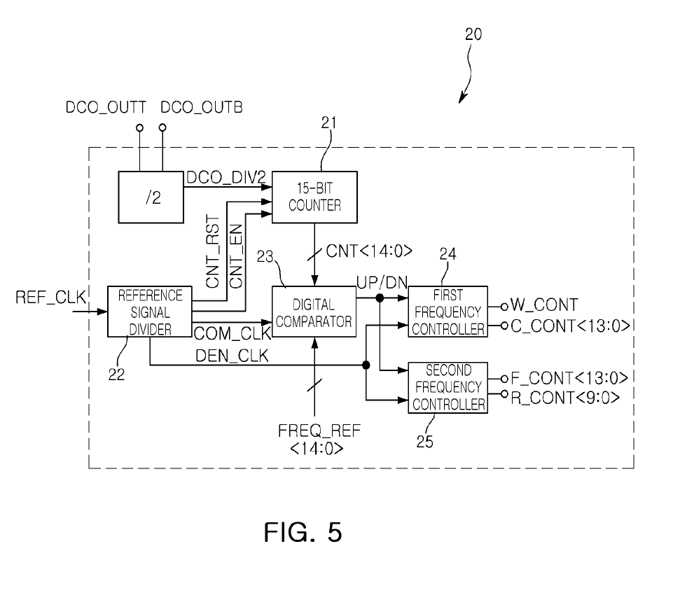

FIG. 5 is a block diagram illustrating a frequency control unit in the control apparatus for a digitally controlled oscillator of FIG. 1 in detail.

Referring to FIG. 5, the frequency control unit 20 may include a counter 21, a reference signal divider 22, a digital comparator 23, a first frequency controller 24, and a second frequency controller 25.

The reference signal divider 22, a signal generator generating clock signals, may transfer the clock signals to the counter 21, the digital comparator 23, the first frequency controller 24, and the second frequency controller 25. The counter 21, the digital comparator 23, the first frequency controller 24, and the second frequency controller 25 may be operated according to input clock signals.

The counter 21 may receive the output signal of the digitally controlled oscillator to determine the frequency of the output signal from the number of bits counted for a unit time. When the output signal of the digital controlled oscillator has a high frequency, the counter 21 may divide and count the bits of the output signal. The counter 21 may be operated according to clock signals CNT_CLK and CNT_EN generated by the reference signal divider 22. When the clock signal CNT_EN is input to the counter 21, the frequency of the output signal determined by the counter 21 is transferred to the digital comparator 23. In addition, when a clock signal CNT_RST is applied to the counter, the counter may be initialized.

The digital comparator 23 may receive a signal CNT <14:0> and a signal FREQ_REF <14:0> and compare frequencies of two signals to generate an UP/DN signal. The signal CNT <14:0>, a signal generated by the counter 21, may be a digital signal having 15 bits. The signal FREG_REF <14:0> has a predetermined reference frequency and may be a digital signal having 15 bits. The digital comparator 23 determines whether the signal CNT <14:0> is higher or lower than the signal FREQ_REF <14:0> to generate the signal UP/DN, and the generated signal UP/DN may be in turn input to the first and second frequency controllers 24 and 25.

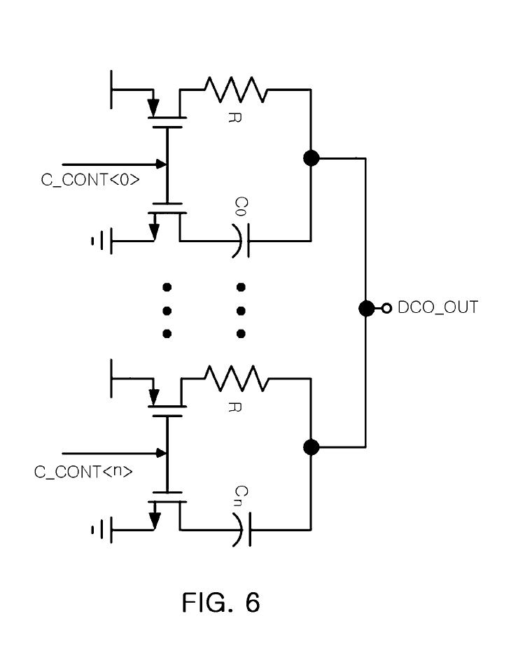

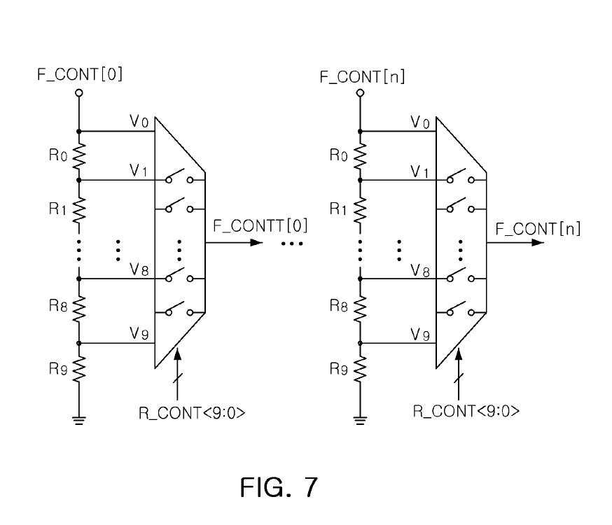

The first frequency controller 24 may receive the signal UP/DN generated by the digital comparator 23 and a clock signal DEN_CLK generated by the reference signal divider 22 to generate control signals W_CONT and C_CONT <13:0>. The second frequency controller 25 may receive the signal UP/DN generated by the digital comparator 23 and the clock signal DEN_CLK generated by the reference signal divider 22 to generate control signals F_CONT <13:0> and R_CONT <9:0>. The control signals W_CONT and C_CONT <13:0> may be digital signals having a plurality of bits and may control capacitor units of a capacitor bank included in the digitally controlled oscillator. The control signals F_CONT <13:0> and R_CONT <9:0> may control voltage applied to the varactor included in the digitally controlled oscillator to control capacitance of the varactor. That is, the control signals generated by the first and second frequency controller 24 and 25 control the capacitance of the capacitor bank and the varactor to control the frequency of the output signal of the digital controlled oscillator. The method of controlling capacitance according to the control signals will be described with reference to FIGS. 6 and 7.

FIG. 6 is a circuit diagram illustrating a capacitor bank controlled according to the frequency control unit of FIG. 5.

Referring to FIG. 6, a capacitor bank may be formed by connecting a plurality of cells in parallel, and in each of the plurality of cells, a resistor R and capacitor units C₀ and Cₙ are connected in parallel. The plurality of cells each may include n-type and p-type MOSFETs. Each of the MOSFET serves as a switch and may be turned-on or turned-off according to a digital signal (hereinafter, the MOSFET is referred to as a switch). The resistor R may prevent a floating phenomenon occurring when the capacitor units are turned-off.

A digital signal applied to the switch of the capacitor bank is the signal C_CONT <13:0> generated by the first frequency controller 24 and respective bits of the signal C_CONT <13:0> may be input to respective cells. When it is determined that the frequency of the output signal of the digitally controlled oscillator is higher than a predetermined reference frequency, the first frequency controller 24 may generate a digital signal having a value of “1”. When it is determined that the frequency of the output signal of the digitally controlled oscillator is lower than a predetermined reference frequency, the first frequency controller 24 may generate a digital signal having a value of “0”. In the cells of the capacitor bank, the switches may be turned-on when the signal C_CONT <13:0> has a value of “1” and may be turned-off when the signal C_CONT <13:0> has a value of “0”. The cells of the capacitor bank are connected to each other in parallel and thus, when the switches are turned-on, capacitance is increased and when the switches are turned-off, capacitance is decreased.

Therefore, when it is determined that the frequency of the output signal of the digitally controlled oscillator is higher than a predetermined reference frequency, the switches are turned-on and thus, capacitance is increased. When it is determined that the frequency of the output signal of the digitally controlled oscillator is lower than a predetermined reference frequency, the switches are turned-off and thus, capacitance is decreased.

The frequency of the output signal of the digitally controlled oscillator varies according to capacitance and therefore, may be controlled by controlling the capacitance of the capacitor bank.

FIG. 7 is a circuit diagram depicting a varactor controlled according to the frequency control unit of FIG. 5.

Referring to FIG. 7, the digitally controlled oscillator may include a voltage control unit of the varactor. Since capacitance is increased in accordance with an increase in voltage applied to the varactor, the varactor included in the digitally controlled oscillator may control capacitance by controlling the voltage applied to the varactor. The voltage applied to the varactor is controlled by a voltage dividing scheme and may be divided according to a resistance value. The voltage control unit of the varactor includes a plurality of resistors R₀, R₁, R₈, and R₉, and the plurality of resistors R₀, R₁, R₈, and R₉ may each be connected to switches. The switches may receive the signals outputted from the second frequency controller and be turned-on or turned-off to control output voltages V₀, V₁, V₈, and V₉ according to the opening and closing thereof.

In addition, a gain of the output signal of the digital controlled oscillator may be constantly maintained by controlling the capacitance of the varactor. The gain of the output signal of the digitally controlled oscillator may be a variance in frequency per least significant bit (LSB). The gain of the output signal of the digitally controlled oscillator may be constantly maintained within a wide frequency tuning range and phase noise may be reduced as a value of the gain is smaller.

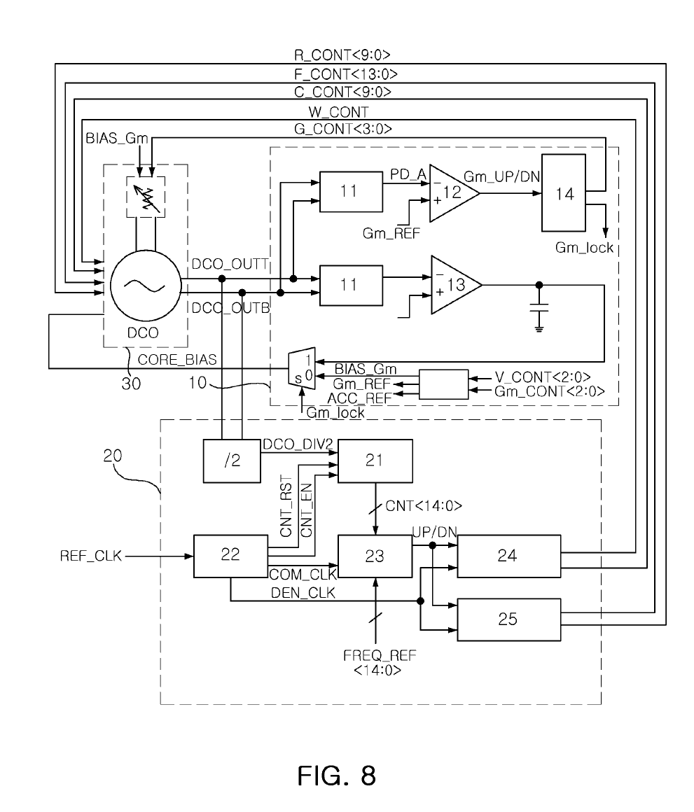

FIG. 8 is a block diagram depicting the control apparatus for a digitally controlled oscillator according to the embodiment of the present invention.

Referring to FIG. 8, the control apparatus for a digitally controlled oscillator may include the digitally controlled oscillator core unit 30, the amplitude control unit 10, and the frequency control unit 20.

The digitally controlled oscillator core unit 30 may include the negative transconductance circuit, the capacitor bank, and the varactor and may be controlled according to the digital signals generated by the amplitude control unit and the frequency control unit. The amplitude control unit 10 may include the negative transconductance control circuit and the negative transconductance control circuit may compensate for changes in amplitude according to parasitic resistance due to the passive inductor element included in the digitally controlled oscillator core unit to constantly maintain the amplitude of the signal output from the core unit. The amplitude of the signal output from the core unit is maintained to have a predetermined amplitude value or more, such that current flowing in the core unit may be increased.

The capacitance of the capacitor bank may be controlled according to the digital signal generated by the first frequency controller included in the frequency control unit and the frequency of the signal output from the core unit may be controlled by controlling the capacitance of the capacitor bank. That is, the capacitor bank may be controlled to compensate for changes in frequency according to the PVT conditions.

The varactor is provided to finely control the frequency of the signal output from the core unit and the capacitance of the varactor may be controlled according to the digital signal generated by the second frequency controller included in the frequency control unit. The capacitance of the varactor is increased as the voltage applied to the varactor is increased and may be controlled by dividing the voltage applied to the varactor.

As set forth above, it is possible to control the amplitude of the digitally controlled oscillator using the digital signal generated by the amplitude control unit and compensate for changes in frequency generated by the PVT conditions using the digital signal generated by the frequency control unit.

While the present invention has been shown and described in connection with the embodiments, it will be apparent to those skilled in the art that modifications and variations can be made without departing from the spirit and scope of the invention as defined by the appended claims.

What is claimed is:

1. A control circuit for a digitally controlled oscillator, comprising:
a peak detection circuit detecting amplitude of a signal output from the digitally controlled oscillator; and
a transconductance control circuit comparing an output of the peak detection circuit with a predetermined reference signal to control a transconductance value of a negative transconductance circuit included in the digitally controlled oscillator.

2. The control circuit for a digitally controlled oscillator of claim 1, wherein the transconductance control circuit includes:
a first comparator comparing a magnitude of the amplitude of the signal output from the digitally controlled oscillator with a magnitude of amplitude of a predetermined first reference signal to generate a digital output signal according to comparison results.

3. The control circuit for a digitally controlled oscillator of claim 2, wherein the first comparator generates a logic high signal as the digital output signal when the magnitude of the amplitude of the signal output from the digitally controlled oscillator is lower than that of the first reference signal and generates a logic low signal as the digital output signal when the magnitude of the amplitude of the signal output from the digitally controlled oscillator is higher than that of the first reference signal.

4. The control circuit for a digitally controlled oscillator of claim 2, wherein the transconductance control circuit includes:
a transconductance bank including a plurality of transconductance unit cells operated according to the digital output signal generated by the first comparator.

5. The control circuit for a digitally controlled oscillator of claim 4, wherein the transconductance unit cells each are sequentially operated when the digital output signal is a logic high signal.

6. The control circuit for a digitally controlled oscillator of claim 1, wherein the transconductance control circuit includes:
a second comparator comparing the signal output from the digitally controlled oscillator with a predetermined second reference signal to generate an analog control signal according to comparison results.

7. A control circuit for a digitally controlled oscillator, comprising:
a counter circuit detecting a frequency of a signal output from the digitally controlled oscillator;
a first frequency controller comparing an output of the counter circuit with a predetermined reference frequency to control capacitance of a capacitor bank included in the digitally controlled oscillator; and
a second frequency controller detecting the output of the counter circuit to control capacitance of a varactor included in the digitally controlled oscillator.

8. The control circuit for a digitally controlled oscillator of claim 7, wherein the first frequency controller generates a logic high signal as a digital signal when it is determined that the frequency of the signal output from the digitally controlled oscillator is higher than the predetermined reference frequency and generates a logic low signal as a digital signal when it is determined that the frequency of the signal output from the digitally controlled oscillator is lower than the predetermined reference frequency.

9. The control circuit for a digitally controlled oscillator of claim 8, wherein the capacitor bank includes a plurality of cells in which resistors and capacitor units are connected in parallel, the capacitor units being selectively controlled by a plurality of bits output from the first frequency controller.

10. The control circuit for a digitally controlled oscillator of claim 7, wherein the varactor is controlled according a magnitude of a voltage applied thereto, the magnitude of the voltage being controlled by a plurality of bits output from the second frequency controller.

11. The control circuit for a digitally controlled oscillator of claim 7, wherein a gain of the digitally controlled oscillator is constantly maintained by the plurality of bits output from the second frequency controller.

12. A control apparatus for a digitally controlled oscillator, comprising:
a digitally controlled oscillator core unit including a negative transconductance circuit, a capacitor bank, and a varactor;
an amplitude control unit including a peak detection circuit detecting amplitude of a signal output from the digitally controlled oscillator core unit and a transconductance control circuit comparing an output of the peak detection circuit with a predetermined reference signal to control a transconductance value of the negative transconductance circuit; and
a frequency control unit controlling capacitance of the capacitor bank and the varactor to control a frequency of the signal output from the digitally controlled oscillator core unit.

13. The control apparatus for a digitally controlled oscillator of claim 12, wherein the transconductance control circuit includes a first comparator comparing a magnitude of the amplitude of the signal output from the digitally controlled oscillator core unit with a magnitude of amplitude of a predetermined first reference signal to generate a digital output signal according to comparison results.

14. The control apparatus for a digitally controlled oscillator of claim 13, wherein the first comparator generates a logic high signal as the digital output signal when the magnitude of the amplitude of the signal output from the digitally controlled oscillator is lower than that of the first reference signal and generates a logic low signal as the digital output signal when the magnitude of the amplitude of the signal output from the digitally controlled oscillator is higher than that of the first reference signal.

15. The control apparatus for a digitally controlled oscillator of claim 12, wherein the frequency circuit unit includes:
a counter circuit detecting the frequency of the signal output from the digitally controlled oscillator core unit;
a first frequency controller comparing an output of the counter circuit with a predetermined reference frequency to control the capacitance of the capacitor bank; and
a second frequency controller detecting the output of the counter circuit to control the capacitance of the varactor.

16. The control apparatus for a digitally controlled oscillator of claim 15, wherein the first frequency controller generates a logic high signal as a digital signal when it is determined that the frequency of the signal output from the digitally controlled oscillator core unit is higher than the predetermined reference frequency and generates a logic low signal as a digital signal when it is determined that the frequency of the signal output from the digitally controlled oscillator is lower than the predetermined reference frequency.

17. The control circuit for a digitally controlled oscillator of claim 16, wherein the capacitor bank includes a plurality of cells in which resistors and capacitor units are connected in parallel, the capacitor units being selectively controlled by a plurality of bits output from the first frequency controller.

18. The control apparatus for a digitally controlled oscillator of claim 15, wherein the varactor is controlled according to a magnitude of a voltage applied thereto, the magnitude of the voltage being controlled by a plurality of bits output from the second frequency controller.
